(19) United States
(12) Patent Application Publication
(10) Pub. No.: US 2009/0113546 A1
(43) Pub. Date: Apr. 30, 2009

(54) MEMORY SYSTEM FOR SENSING ATTACK

(75) Inventors: Sun Kwon KIM, Suwon-si (KR); Byeong Hoon LEE, Seoul (KR); Ki Hong KIM, Suwon-si (KR); Hyuck Jun CHO, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/258,672

(22) Filed: Oct. 27, 2008

(30) Foreign Application Priority Data
Oct. 30, 2007 (KR) 10-2007-0109598

(51) Int. Cl. G06F 12/14; G06F 12/00; G06F 11/00; G11C 29/52; G06F 12/16

(52) U.S. Cl. 726/22; 726/34; 711/161; 711/115; 714/805; 714/E11.001; 711/E12.001; 711/E12.103; 711/E12.091

(57) ABSTRACT

A memory system includes a main memory, a sub-memory, a controller, first and second data readers and a comparator. The main memory stores data and the sub-memory stores data extracted from the data stored in the main memory for detection of an attack. The controller controls operations of the memory system through interfacing with a host. The first data reader is configured to read first data from the main memory based on address information from the controller. The second data reader is configured to store information relating to second data stored in the sub-memory and to read the second data from the sub-memory based on address information from the controller which is the same as the address information received by the first data reader. The comparator compares the first data read by the first data reader with the second data read by the second data reader to detect the attack.

### PRIORITY CLAIM

A claim of priority is made to Korean Patent Application No. 10-2007-0109598, filed on Oct. 30, 2007, in the Korean Intellectual Property Office, the subject matter of which is hereby incorporated by reference.

### SUMMARY

Embodiments of the present invention relate to a memory system, and more particularly, to a memory system for sensing an attack, such as a laser attack or a power attack, for example.

Since credit cards were introduced in the 1920s, use of cards has been expanded to include debit cards, identification, stock cards, department cards, etc., as well as credit cards. Recently, integrated circuit (IC) cards, which may be referred to as small computers or microprocessor cards, have attracted attention due to convenience, safety and versatility.

An IC card is configured by attaching a thin semiconductor device to a plastic card, about the size of a credit card. Since the IC cards are more secure than conventional cards, which use magnetic strips, and there is no concern of data loss, IC cards are generally considered the next-generation multimedia information medium. In an IC card, a semiconductor chip, having a thickness of about 0.5 mm, is formed or embedded in plastic, having substantially the same size and thickness of a typical credit card, in the form of chip-on-board (COB).

An IC card that includes a microprocessor is referred to as a “smart card.” The smart card includes a central processing unit, electrically erasable programmable read-only memory (EEPROM) for storing application programs, read only memory (ROM), and random access memory (RAM). The smart card may contain information, such as a user's private key, personal information and key code for security, and provides higher security than conventional magnetic strip cards. It may also store a large amount of data, function as an electronic-purse and can be equipped with various applications. Since the smart card provides two-way communication, distributed data processing and protection of information, it has been used in various fields of applications, such as finance, distribution, factory automation, office automation, medical service, traffic, social security, mobile communication, pay phone, cable television (TV), electric power, gas and water services, education, credit cards, debit cards, prepaid cards, information security, and home banking, for example, and may be used in many other fields of applications.

As stated above, because a smart card has higher security than a conventional magnetic strip card, it may be used to store private or sensitive information, requiring security. In other words, data stored in the smart card may need to be kept securely. If such data were to be revealed to third parties, it may negatively effect both of the user and system operator.

Circuits which are sensitive to security or perform important functions, like smart cards, are equipped with devices and methods for detecting and handling external attacks. For instance, a smart card may include a cryptographic barrier generated with complicated codes to prevent unauthorized access so called “tampering.”

Regardless, illegal manipulation of smart cards still occurs. For instance, circuits may be attacked by externally applying abnormal conditions, such as power supply voltage, operating frequency and/or operating temperature, so that the cryptographic barrier does not function normally. Likewise, radiating a particular portion of a smart card with a laser beam may be used to make circuits act abnormally.

Embodiments of the present invention provide a memory system for detecting attacks, e.g., from hackers, and protecting information stored in a memory area in a circuit, such as a smart card, in which security is important.

According to various embodiments of the present invention, there is provided a memory system that includes a main memory, a sub-memory, a controller, first and second data readers and a comparator. The main memory is configured to store data and the sub-memory is configured to store data extracted from the data stored in the main memory for detection of an attack. The controller is configured to control operations of the memory system through interfacing with a host system. The first data reader is configured to read first data from the main memory based on address information from the controller. The second data reader is configured to store information relating to second data stored in the sub-memory and to read the second data from the sub-memory based on address information from the controller which is the same as the address information received by the first data reader. The comparator is configured to compare the first data read by the first data reader with the second data read by the second data reader to detect the attack.

The sub-memory may back up all data stored at a particular address of the main memory, or only a particular bit in data stored at a particular address of the main memory. The second data reader may store information about the particular address and read the second data from the sub-memory upon receiving the address information, which is the same as the address information about the particular address.

The sub-memory may store 1-bit data representing data stored at each address of the main memory. The 1-bit data may be data stored at a particular input/output (I/O) number per address or a parity bit calculated per address.

The controller may send a repetitive read address to the first data reader as many times as a repetitive read count based on the repetitive read address and the repetitive read count, which may be preset. The controller may change the repetitive read count based on external input information. The first data reader may store data repeatedly read from the main memory in the sub-memory.

### BRIEF DESCRIPTION OF THE DRAWINGS

The embodiments of the present invention will be described with reference to the attached drawings, in which:

FIG. 1 is a block diagram of a memory system, according to a first embodiment of the present invention;

FIG. 2 is a flowchart of a method of detecting an attack using the memory system illustrated in FIG. 1;

FIG. 3 is a block diagram of a memory system, according to a second embodiment of the present invention;

FIG. 4 is a flowchart of a method of detecting an attack using the memory system illustrated in FIG. 3;

FIG. 5 is a block diagram of a memory system, according to a third embodiment of the present invention;

FIG. 6 is a flowchart of a method of detecting an attack using the memory system illustrated in FIG. 5;

FIG. 7 is a block diagram of a memory system, according to a fourth embodiment of the present invention;

FIG. 8 is a flowchart of a method of detecting an attack using the memory system illustrated in FIG. 7;

FIG. 9 is a block diagram of a memory system, according to a fifth embodiment of the present invention; and

FIG. 10 is a flowchart of a method of detecting an attack using the memory system illustrated in FIG. 9.

### DETAILED DESCRIPTION OF THE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements. Also, in the drawings, the sizes and relative sizes of components and regions may be exaggerated for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc., may be used herein to describe various elements, these elements should not be limited by these terms. These terms are only used to distinguish one element from another. For example, a first signal could be termed a second signal, and similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

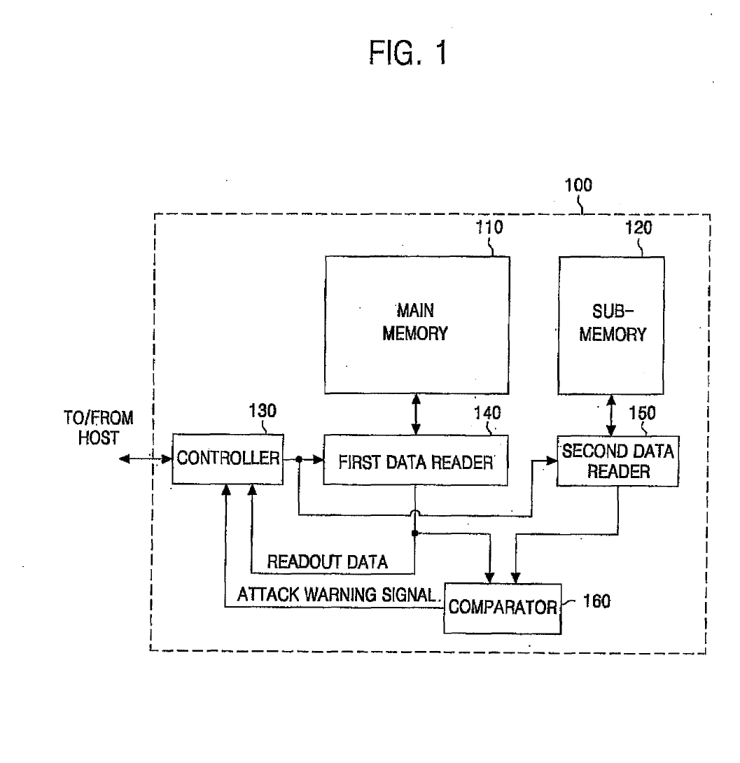

FIG. 1 is a block diagram of a memory system 100, according to a first exemplary embodiment of the present invention. The memory system 100 includes a main memory 110, a sub-memory 120, a controller 130, a first data reader 140, a second data reader 150, and a comparator 160.

The main memory 110 stores data, and may be any type of appropriate memory. For instance, when the memory system 100 is a flash memory system, the main memory 110 includes a memory block including multiple memory cells.

The sub-memory 120 stores data extracted from the data stored in the main memory 110 for attack detection. For instance, in various embodiments, the sub-memory 120 may back up all data stored at a particular address in the main memory 110, store 1-bit data at a particular input/output (I/O) number per address in the main memory 110 (e.g., data at I/O number “n” at an address of “n” in the main memory 110), or store a parity bit calculated per address in the main memory 110. Alternatively, the sub-memory 120 may selectively back up particular bits of data stored at a particular address in the main memory 110. For example, the sub-memory 120 may store only even numbered bits in data at an address of “0” or only the first 20 bits in the data at the address of “0”. When storing 1-bit data at a particular I/O number or storing a parity bit, the storing may be performed for every address, or alternatively, just for selected addresses. For example, in various embodiments, after even or odd addresses are selected, the sub-memory 120 may store 1-bit data at the particular I/O number in each even or odd address, or store a parity bit calculated for each even or odd address. In other embodiments, 1-bit data and/or a parity bit may be alternately stored. For example, the sub-memory 120 may store 1-bit data at a particular I/O number for each even address and store a parity bit for each odd address. Accordingly, it is understood that extracting the attack detection data to be stored in the sub-memory 120 from the data stored in the main memory 110 may be performed in a variety ways.

Further, the sub-memory 120 may select (e.g., through the controller 130 and/or the second data reader 150) a first address group and a second address group from addresses of the main memory 110. The first address group may be matched with either data at the particular I/O number per address or the parity bit calculated per address, and the second address group may be matched with the other one of the data at the particular I/O number per address or the parity bit calculated per address.

The sub-memory 120 is a storage area logically separated from the main memory 110, although it may not be physically separated from the main memory 110. For instance, in various embodiments, the main memory 110 and the sub-memory 120 may be implemented in a single memory block including multiple memory cells. Alternatively, the sub-memory 120 may be implemented by logic elements, such as registers or logic gates, instead of memory cells.

The controller 130 controls the operation of the memory system 100 through interfacing with a host system (not shown). Also, the controller 130 sends data read out by the first data reader 140 to the host system and, when an attack (e.g., laser attack) is detected in the main memory 110, the controller 130 informs the host system of the attack.

The first data reader 140 reads data from the main memory 110 based on address information received from the controller 130, and the second data reader 150 reads the data from the sub-memory 120. In addition, the second data reader 150 may store one or more properties, parameters or other information relating to the data stored in the sub-memory 120, and may read the data from the sub-memory 120 when predetermined data read conditions are satisfied. For example, when all data at a particular address in the main memory 110 is stored in the sub-memory 120, the particular address is stored in the second data reader 150. When 1-bit at a particular I/O number in each address of the main memory 110 is stored in the sub-memory 120, the I/O number selection information is stored in the second data reader 150. When a parity bit calculated for each address of the main memory 110 is stored in the sub-memory 120, information indicating this fact is stored in the second data reader 150.

When the second data reader 150 receives the same address information as that sent to the first data reader 140 from the controller 130, it determines whether to read data from the sub-memory 120 based on the data read conditions and reads the data from the sub-memory 120. For instance, when the address received from the controller 130 is the same as a particular address previously stored in the second data reader 150, the second data reader 150 may read data from the sub-memory 120. Alternatively the second data reader 150 may read 1-bit of the data at a particular I/O number in the address or a parity bit corresponding to the address.

The comparator 160 compares first data read by the first data reader 140 with second data read by the second data reader 150 and determines the existence or non-existence of an attack, such as a laser attack. More particularly, when the first data and the second data are different, the comparator 160 determines that an attack has occurred in the main memory 110 and outputs an attack warning signal to the controller 130. The comparator 160 may compare the first data with the second data while the first data is being read, or after the first data reader 140 reads the first data from a current address and before the first data reader 140 reads data from a subsequent address, for example.

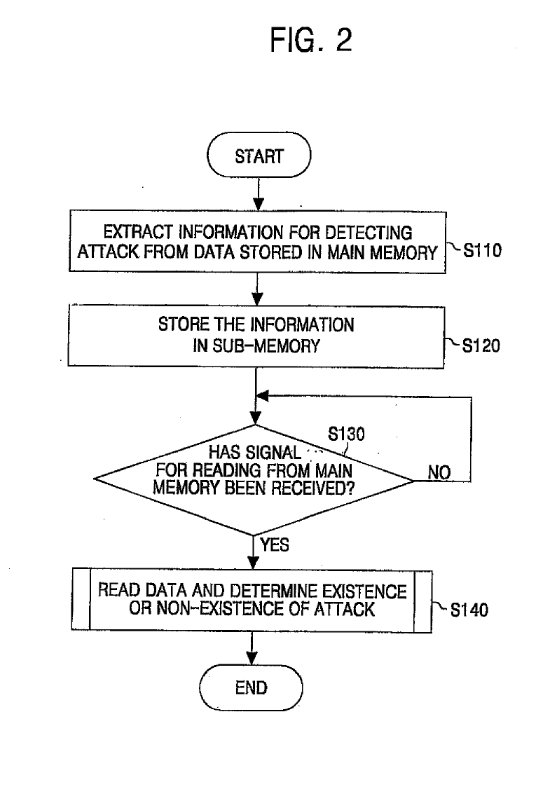

FIG. 2 is a flowchart of a method of detecting an attack using the memory system 100 illustrated in FIG. 1, according to an exemplary embodiment. Referring to FIGS. 1 and 2, the controller 130 of the memory system 100 extracts information for detecting an attack from the main memory 110 in operation S110 and stores the extracted information in the sub-memory 120 in operation S120. As has been described above, the information for detecting an attack, for example, may be all data stored at a particular address in the main memory 110, 1-bit data at a particular I/O number per address in the main memory 110, or a parity bit calculated per address.

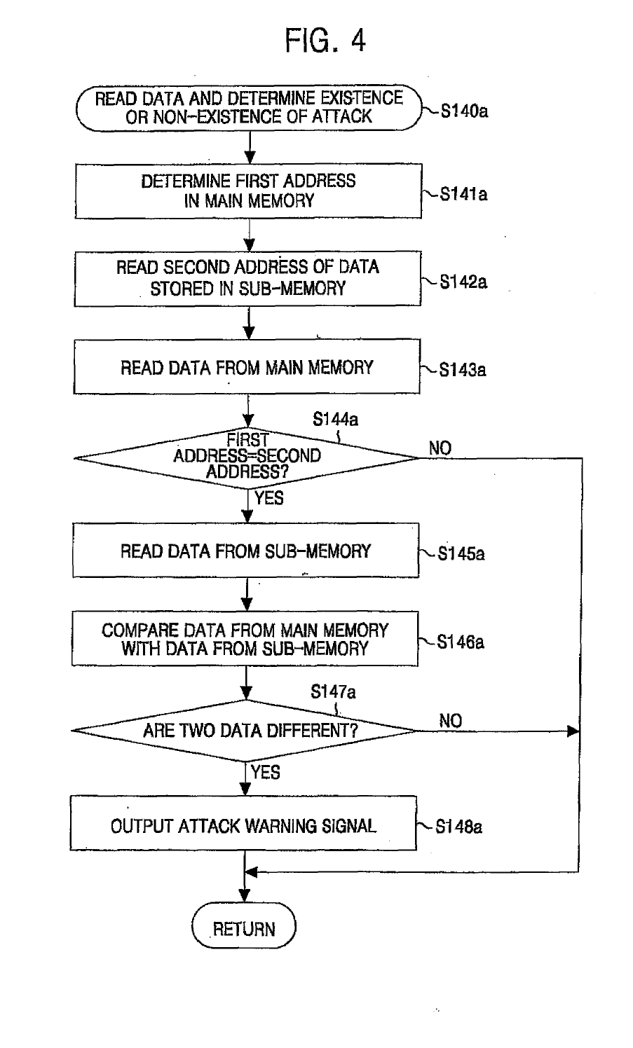

When a signal for detecting data from a particular address in the main memory 110 is received from an external host system in operation S130, the controller 130 sends the address information to the first data reader 140 and the second data reader 150 to read data from the main memory 110 and the sub-memory 120, respectively. The controller 130 determines whether an attack has occurred in the main memory 110 according to the process depicted as operation S140, examples of which are discussed below with respect to FIGS. 4, 6 and 8.

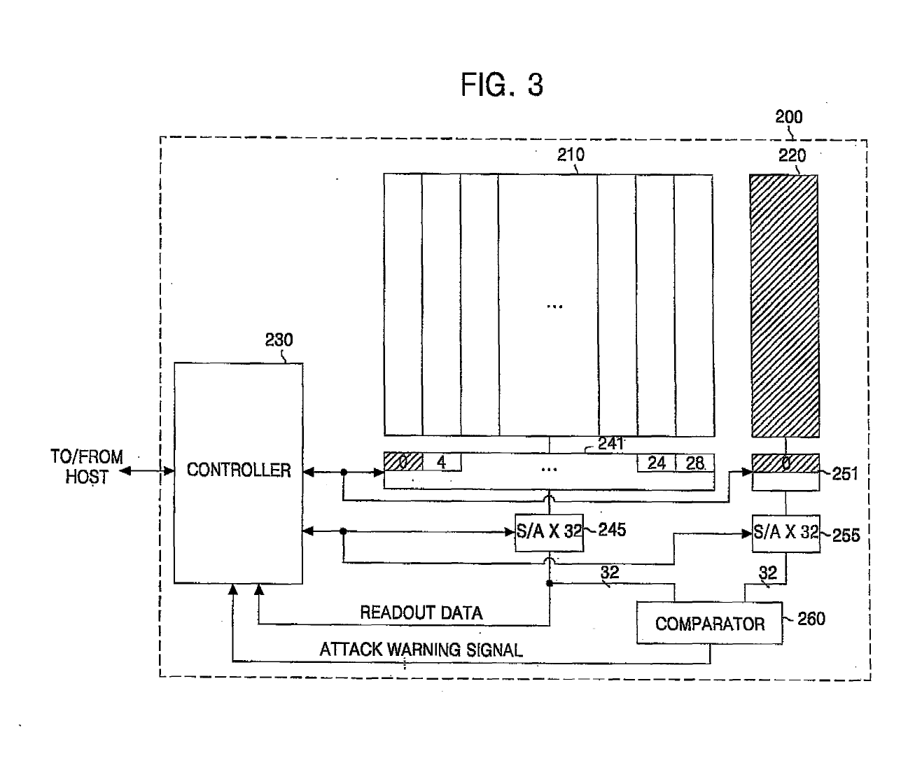

FIG. 3 is a block diagram of a memory system 200, according to a second exemplary embodiment of the present invention. The memory system 200 backs up or stores all data of a particular address, and determines the existence or non-existence of an attack, such as a laser attack, based on the backup data.

Referring to FIG. 3, the memory system 200 includes a main memory 210, a sub-memory 220, a controller 230, a first multiplexer 241, multiple first sense amplifiers (S/As) 245, a second multiplexer 251, multiple second S/As 255, and a comparator 260. The first multiplexer 241 and the first S/As 245 correspond to the first data reader 140, illustrated in FIG. 1, and the second multiplexer 251 and the second S/As 255 correspond to the second data reader 150, illustrated in FIG. 1.

FIG. 3 illustrates an example in which all data at an address of “0” in the main memory 210 is stored in the sub-memory 220. Accordingly, address information “0” is stored in the second multiplexer 251. When the second multiplexer 251 receives a command from the controller 230 to read data from the address of “0”, it sends the data (e.g., 32 bits) stored in the sub-memory 220 to the comparator 260 via the second S/As 255.

FIG. 4 is a flowchart of a method of detecting an attack using the memory system 200 illustrated in FIG. 3, according to an exemplary embodiment. FIG. 4 illustrates an example of operation S140 of FIG. 2 for reading data and determining the existence or non-existence of an attack in the process beginning at operation S140a. Referring to FIGS. 3 and 4, when a signal for detecting data from a particular address in the main memory 210 is received from an external host system, the controller 230 determines an address (hereinafter, referred to as a “first address”) from which data is read in the main memory 210 in response to the received signal in operation S141a and reads an address (hereinafter, referred to as a “second address”) corresponding to data stored in the sub-memory 220 in operation S142a. The first multiplexer 241 reads data from the first address in the main memory 210 in operation S143a. In other words, the first multiplexer 241 sends the data stored at the first address in the main memory 210 to the first S/As 245.

It is determined in operation S144a whether the first address is the same as the second address, previously stored in the second multiplexer 251. When the first and second addresses are the same, the second multiplexer 251 reads data from the sub-memory 220 in operation 145a and sends the data to the comparator 260 via the second S/As 255. Then, the comparator 260, which also receives the data read from the first address in the main memory 210 via the first S/As 245, compares the data from the main memory 210 with the data from the sub-memory 220 in operation S146a. When the comparator 260 determines that the two data are different from each other in operation S147a, it outputs an attack warning signal in operation S148a. The attack warning signal may be output, for example, by way of an alarm sound or lamp. When the first and second address are not the same, as determined in operation S144a, or when the two data are not different, as determined in operation S147a, the determining process ends, returning to the main process, without outputting the attack warning signal.

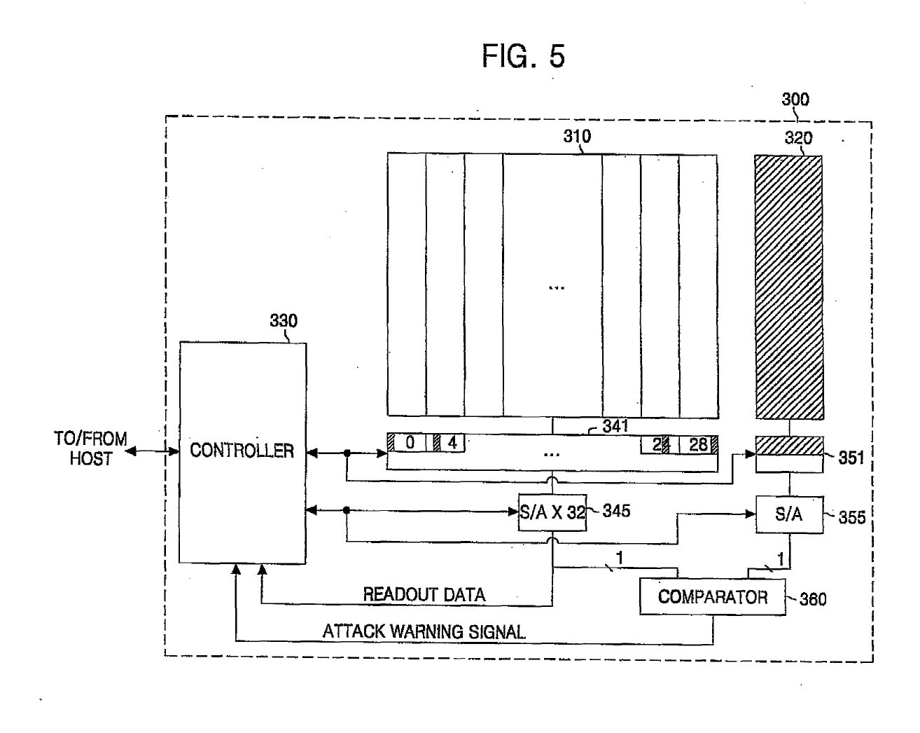

FIG. 5 is a block diagram of a memory system 300, according to a third exemplary embodiment of the present invention. The memory system 300 stores 1-bit data at a particular I/O number per each address in a main memory, and determines the existence or non-existence of an attack, such as a laser attack, using the 1-bit data.

Referring to FIG. 5, the memory system 300 includes a main memory 310, a sub-memory 320, a controller 330, a first multiplexer 341, first S/As 345, a second multiplexer 351, second S/As 355, and a comparator 360. The first multiplexer 341 and the first S/As 345 correspond to the first data reader 140, illustrated in FIG. 1, and the second multiplexer 351 and the second S/As 355 correspond to the second data reader 150, illustrated in FIG. 1.

FIG. 5 illustrates an example in which an n-th I/O bit of data at an address of “n” in the main memory 310 is stored in the sub-memory 320. For example, a 0th I/O bit of data at an address of “0”, a 4th I/O bit of data at an address of “4”, and an 8th I/O bit of data at an address of “8” are stored in the sub-memory 320. In the same manner, data up to an address of “n” are stored in the sub-memory 320. Accordingly, I/O selection information per address is stored in the second multiplexer 351. When the second multiplexer 351 receives a command to read data from a particular address from the controller 330, it sends 1-bit data at an I/O number corresponding to the particular address to the comparator 360 via the second S/As 355.

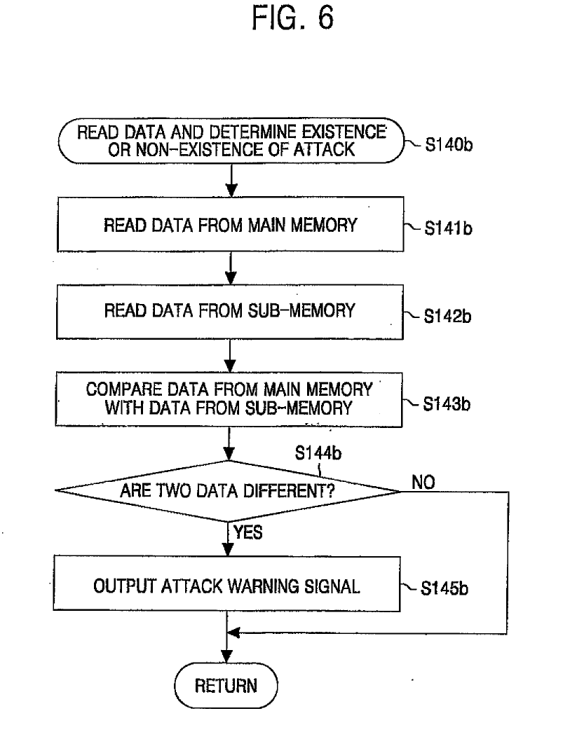

FIG. 6 is a flowchart of a method of detecting an attack using the memory system 300 illustrated in FIG. 5, according to an exemplary embodiment. FIG. 6 illustrates another example of operation S140 of FIG. 2 for reading data and determining the existence or non-existence of an attack in the process beginning at operation S140b. Referring to FIGS. 5 and 6, when a signal for detecting data from a particular address of the main memory 310 is received from an external host system, the controller 330 reads data from the main memory 310 in response to the received signal in operation S141b. Also, the second multiplexer 351 reads I/O data corresponding to the particular address from the sub-memory 320 in operation S142b.

The comparator 360, which receives the data read from the main memory 310 and the data read from the sub-memory 320, detects I/O data from the data read from the main memory 310 based on the I/O selection information and compares the detected I/O data with the I/O data read from the sub-memory 320 in operation S143b. When the comparator 360 determines that the two I/O data are different from each other in operation S144b, it outputs an attack warning signal in operation S145b. The attack warning signal may be output, for example, by way of an alarm sound or lamp. When the two I/O data are not different, as determined in operation S144b, the determining process ends, returning to the main process, without outputting the attack warning signal.

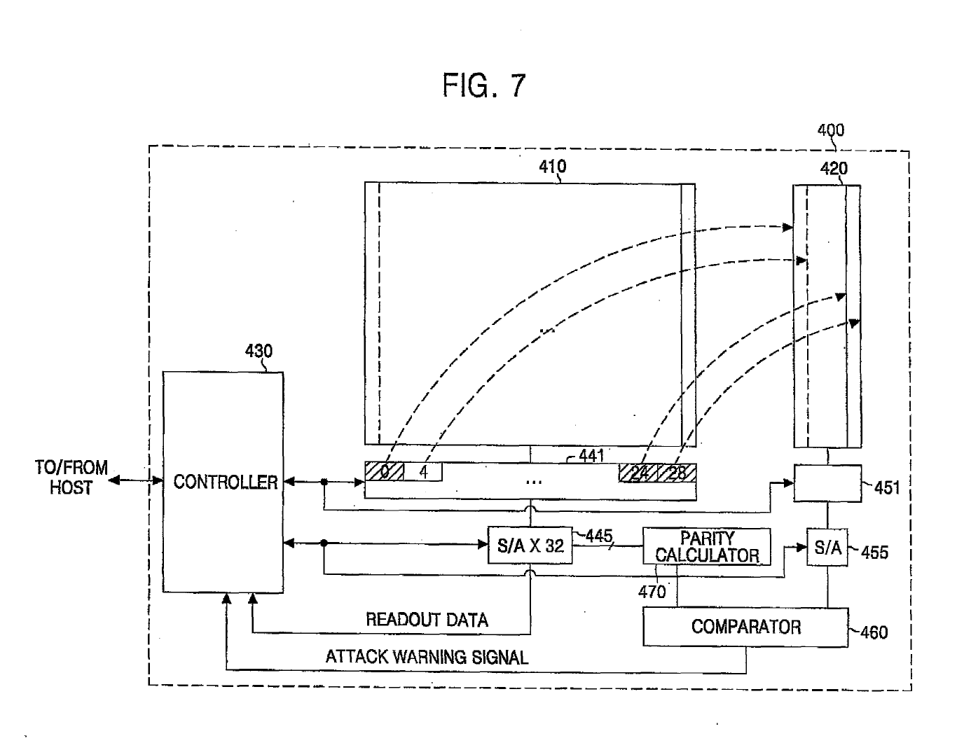

FIG. 7 is a block diagram of a memory system 400, according to a fourth exemplary embodiment of the present invention. The memory system 400 stores a parity bit calculated per address in a main memory and determines the existence or non-existence of an attack, such as a laser attack, using the parity bit.

Referring to FIG. 7, the memory system 400 includes a main memory 410, a sub-memory 420, a controller 430, a first multiplexer 441, first S/As 445, a second multiplexer 451, second S/As 455, a comparator 460, and a parity calculator 470. The first multiplexer 441 and the first S/As 445 correspond to the first data reader 140, illustrated in FIG. 1, and the second multiplexer 451 and the second S/As 455 correspond to the second data reader 150, illustrated in FIG. 1.

The parity calculator 470 calculates a parity bit with respect to data, which has been read by the first multiplexer 441 from a particular address in the main memory 410 and sent through the first S/As 445. The calculated parity bit is compared with a parity bit previously stored in the sub-memory 420.

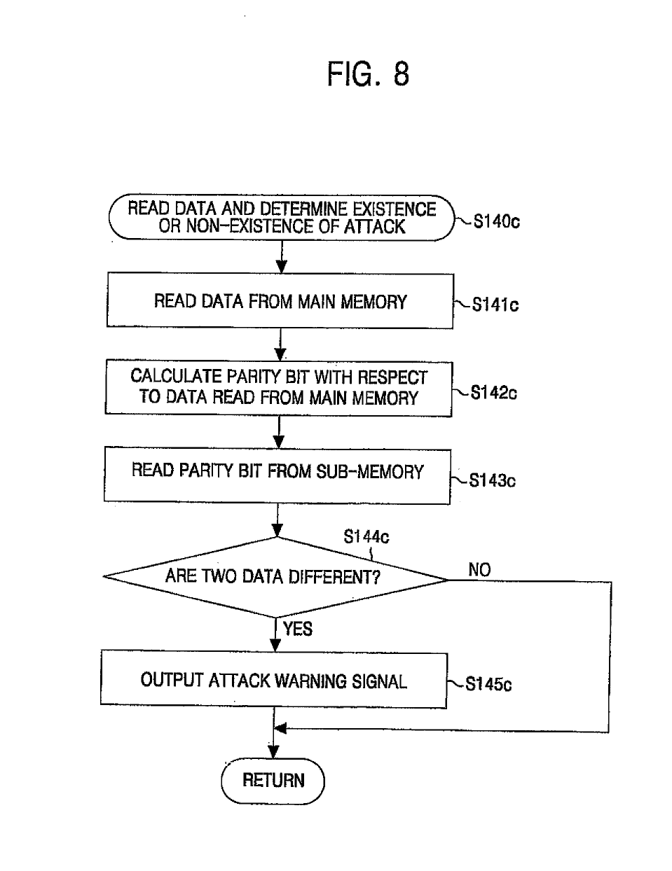

FIG. 8 is a flowchart of a method of detecting an attack using the memory system 400 illustrated in FIG. 7, according to an exemplary embodiment. FIG. 8 illustrates another example of operation S140 of FIG. 2 for reading data and determining the existence or non-existence of an attack in the process beginning at operation S140c. Referring to FIGS. 7 and 8, when a signal for detecting data from a particular address in the main memory 410 is received from an external host system, the controller 430 reads data from the main memory 410 in response to the received signal in operation S141c. A parity bit is calculated from the data read from the main memory 410 in operation S142c. Meanwhile, the second multiplexer 451 reads a parity bit corresponding to the particular address from the sub-memory 420 in operation S143c.

The comparator 460 compares the parity bit calculated in operation S142c with the parity bit read from the sub-memory 420 and determines whether the two parity bits are different from each other in operation S144c. When the comparator 460 determines that the two parity bits are different from each other in operation S144c, it outputs an attack warning signal in operation S145c. The attack warning signal may be output, for example, by way of an alarm sound or lamp. When the two parity bits are not different, as determined in operation S144c, the determining process ends, returning to the main process, without outputting the attack warning signal.

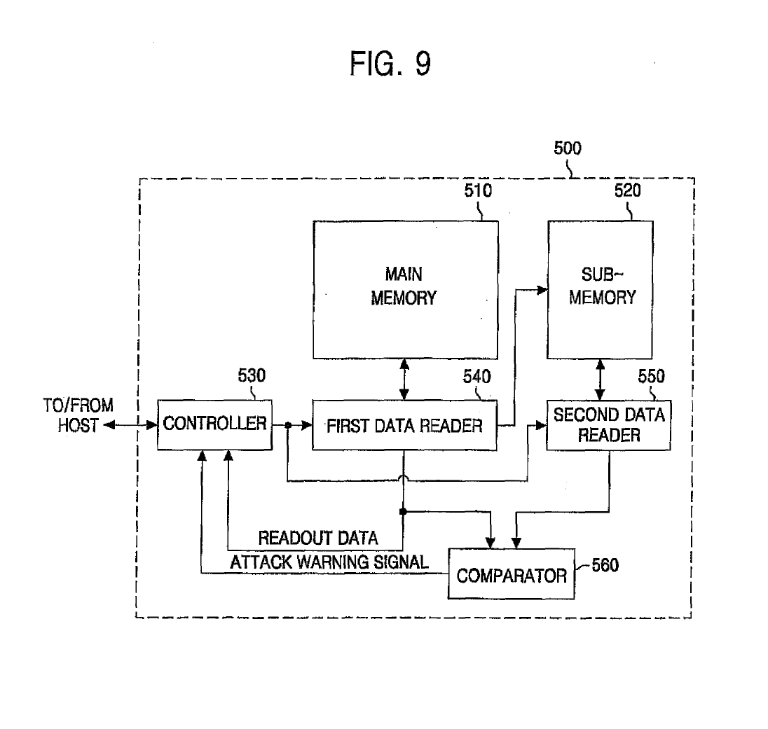

FIG. 9 is a block diagram of a memory system 500, according to a fifth exemplary embodiment of the present invention. The memory system 500 includes a main memory 510, a sub-memory 520, a controller 530, a first data reader 540, a second data reader 550, and a comparator 560. Blocks 510 through 560 illustrated in FIG. 9 respectively correspond to blocks 110 through 160 illustrated in FIG. 1. The functions of the sub-memory 520, the controller 530, the first data reader 540, and the second data reader 550 partially differ from the corresponding functions of the sub-memory 120, the controller 130, the first data reader 140 and the second data reader 150 of FIG. 1. Thus, only the differences will be described with reference to FIG. 9.

The controller 530 sends a repetitive read address to the first data reader 540 a predetermined number of times, as indicated by a repetitive read count, based on the repetitive read address and the repetitive read count, which may be preset. In response, the data at the same address (e.g., of main memory 510) is repeatedly read and compared to previously read data from the repetitive read address to determine whether the data at that address has been attacked. The repetitive read count may vary based on factors, such as a user's selection information, time, operating conditions, etc. Accordingly, the controller 530 may change the repetitive read count based on external input information before starting the operation.

The first data reader 540 is controlled by the controller 530 to store the data repeatedly read from the main memory 510 in the sub-memory 520, which (temporarily) stores the data read by and received from the first data reader 540. In various embodiments, the first data reader 540 may store only data read first or data read most recently from the repetitive read address in the sub-memory 520.

When only data read first is stored, the first data reader 540 sends the data read first from the repetitive read address to the sub-memory 520, which stores the data. Then, when the first data reader 540 subsequently reads data additional times from the repetitive read address, the data is sent to the comparator 560, which compares the subsequently read data with the first read data stored in the sub-memory 520 and sent to the comparator 560 via the second data reader 550. In other words, the comparator 560 compares the stored first read data with second read data from the repetitive read address, then with third read data from the repetitive read address, and so on, until the repetitive reading and comparison are complete. The comparator 560 determines the existence or non-existence of an attack based on the comparison results.

When only most recent data is stored, the first data reader 540 sends the most recently read data from the repetitive read address to the sub-memory 520, which stores the data, e.g., after erasing the previously stored data from the repetitive read address. For example, the first data reader 540 sends first read data from the repetitive read address to the sub-memory 520 to be stored. When second read data is read from the repetitive read address, the comparator 560 compares the second read data with the first read data (stored in the sub-memory 520), and the first data reader 540 erases the first read data from the sub-memory 520 and stores the second read data in the sub-memory 520. Then, when third data is read from the repetitive read address, the comparator 560 compares the third read data with the second read data (stored in the sub-memory 520), and the first data reader 540 erases the second read data from the sub-memory 520 and stores the third read data in the sub-memory 520. This operation is repeated every time data is read from the repetitive read address until last read data is stored in the sub-memory 520. In other words, when the repetitive read count is “n”, the comparator 560 repeats the comparison until data read from the repetitive read address for the n-th time is compared with data read from the repetitive read address for the (n−1)-th time. In various embodiments, the data stored in the sub-memory 520 may be a predetermined number of bits (e.g., 0th through 20th bits) or one particular bit of data corresponding to the repetitive read address. The comparator 560 determines the existence or non-existence of an attack based on the comparison results.

In this example, the first data reader 540 stores only certain data repeatedly read in the sub-memory 520. However, the embodiments are not restricted to the example described above. For example, the first data reader 540 may store all data repeatedly read in the sub-memory 520. In this case, the comparator 560 compares all data at the same time to determine the existence or non-existence of an attack.

The controller 530 may also output signals indicating the beginning and end of the repetitive reading to the second data reader 550. The second data reader 550 reads data from the sub-memory 520 during the repetitive reading.

According to various embodiments of the present invention, at least two of the first through fifth embodiments may be used together. For instance, the fifth embodiment can be used together with one of the first through fourth embodiments. In this case, data read from a predetermined repetitive read address is compared through repetitive reading to determine the existence of non-existence of an attack, and data read from other addresses are compared by a method explained in one of the first through fourth embodiments to determine the existence of non-existence of an attack. In an operation such as this, the sub-memory 520 may include a first memory area for storing repeatedly read data and a second memory area for storing data in accordance with at least one of the other embodiments, e.g., all data read from a particular address of the main memory 510, 1-bit data read from a particular I/O number of each address of the main memory 510, and/or a parity bit calculated per address of the main memory 510. The second data reader 550 may read the data from the first memory area during repetitive reading and otherwise read the data from the second memory area, so that data read by the first data reader 540 is compared with the data read by the second data reader 550 to determine the existence or non-existence of an attack.

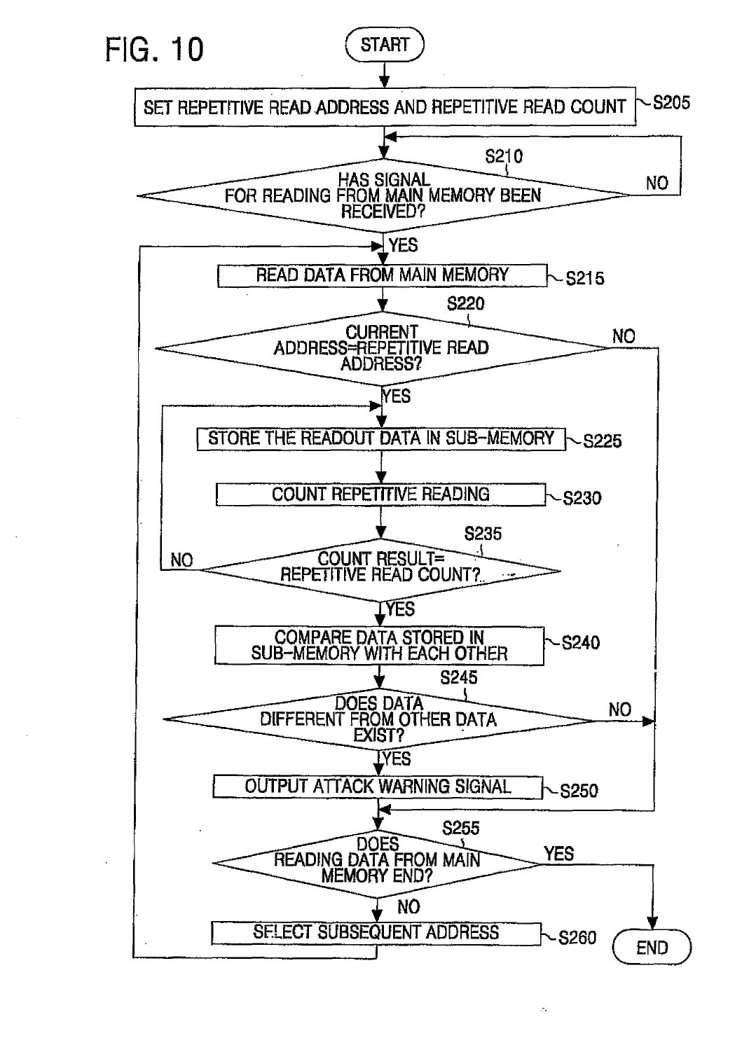

FIG. 10 is a flowchart of a method of detecting an attack, such as a laser attack, using the memory system 500 illustrated in FIG. 9, according to an exemplary embodiment. FIG. 10 illustrates a method for storing all data repeatedly read, e.g., from a predetermined address, from the main memory 510 in the sub-memory 520, during a predetermined repetitive reading term. In the depicted embodiment, the stored data is compared upon ending the predetermined repetitive reading term to determine the existence or non-existence of a laser attack on a memory area corresponding to the predetermined address. Referring to FIGS. 9 and 10, the controller 530 sets a repetitive read address and a repetitive read count in operation S205. The repetitive read address and the repetitive read count may be set based on information provided by an external host system, for example. The repetitive read count may vary with factors such as user setting information and/or operating conditions of the memory system 500.

In operation S210, it is determined when a signal for reading data from a particular address of the main memory 510 has been received from the external host system. The controller 530 then controls the first data reader 540 to read data from the particular address of the main memory 510 in operation S215. The controller 530 also compares the current particular address with the repetitive read address in operation S220. When the current address is not the same as the repetitive read address, the process proceeds to operation S255, discussed below. When the current address is the same as the repetitive read address, the controller 530 controls the first data reader 540 to store the data read from the main memory 510 in the sub-memory 520 in operation S225.

Next, the controller 530 counts the number of repetitive readings in operation S230. When it is determined that the count is less than the repetitive read count in operation S235, operations S225 and S230 are repeated. In other words, the controller 530 repeatedly reads data of the current particular address. When the count result is equal to (or greater than) the repetitive read count, the comparator 560 compares data stored in the sub-memory 520 with each other in operation S240. When it is determined that data different from the other data exists in operation S245, an attack warning signal is output in operation S250. The form of the attack warning signal has been explained with reference to FIG. 8, for example. Otherwise, the process proceeds to operation S255 without outputting the attack warning signal.

In operation S255, it is determined whether reading from the main memory 510 has been completed. When it has not been completed, another (subsequent) address is selected in operation S260 and the operations S215 through S255 are repeated. Otherwise, the process ends.

As indicated above, the method illustrated in FIG. 10 may be combined with at least one of the methods respectively illustrated in FIGS. 2, 4, 6 and 8.

According to the various embodiments described herein, an attack on an IC card, such as a laser attack, can be detected in a memory system storing sensitive information, such as private user keys and personal information requiring security. Accordingly, the information is protected from being revealed and reliability of the memory system is enhanced.

While the present invention has been described with reference to exemplary embodiments, it will be apparent to those skilled in the art that various changes and modifications may be made without departing from the spirit and scope of the present invention. For example, embodiments of the present invention can be used for any kinds of memory systems requiring security that may be exposed to external attacks. For example, the present invention may be incorporated into flash memory systems, memories used in card systems, flash memory in card systems, and the like. Further, the various embodiments are not restricted to laser attacks, and can be used to detect power attacks, for example, performed by instantaneously changing electric power, as well as other types of attacks. Therefore, it should be understood that the above embodiments are not limiting, but illustrative.

What is claimed is:

1. A memory system comprising:
a main memory configured to store data;
a sub-memory configured to store data extracted from the data stored in the main memory for detection of an attack;
a controller configured to control operations of the memory system through interfacing with a host system;
a first data reader configured to read first data from the main memory based on address information from the controller;
a second data reader configured to store information relating to second data stored in the sub-memory and to read the second data from the sub-memory based on address information from the controller which is the same as the address information received by the first data reader; and
a comparator configured to compare the first data read by the first data reader with the second data read by the second data reader to detect the attack.

2. The memory system of claim 1, wherein the sub-memory backs up all data stored at a particular address of the main memory.

3. The memory system of claim 1, wherein the sub-memory stores only a particular bit in data stored at a particular address of the main memory.

4. The memory system of claim 2, wherein the second data reader stores information about the particular address and reads the second data from the sub-memory upon receiving the address information, which is the same as the address information about the particular address.

5. The memory system of claim 1, wherein the sub-memory stores 1-bit data representing data stored at each address of the main memory.

6. The memory system of claim 5, wherein the 1-bit data is one of data stored at a particular input/output (I/O) number per address or a parity bit calculated per address.

7. The memory system of claim 6, wherein the sub-memory selects a first address group and a second address group from addresses of the main memory, matches the first address group with one of data at the particular I/O number per address or the parity bit calculated per address, and matches the second address group with the other one of the particular I/O number per address or the parity bit calculated per address.

8. The memory system of claim 5, wherein the sub-memory stores 1-bit data representing data stored at an address selected from the addresses of the main memory.

9. The memory system of claim 6, wherein the second data reader reads only 1-bit data corresponding to the address information received from the controller, and the comparator detects only 1-bit data corresponding to the particular I/O number of an address corresponding to the address information from the first data or receives a parity bit calculated for the address corresponding to the address information and compares the detected 1-bit data or the parity bit with the 1-bit data read by the second data reader.

10. The memory system of claim 9, further comprising a parity calculator configured to calculate a parity bit with respect to the first data read by the first data reader.

11. The memory system of claim 1, wherein the controller sends a repetitive read address to the first data reader as many times as a repetitive read count based on the repetitive read address and the repetitive read count.

12. The memory system of claim 11, wherein the controller changes the repetitive read count based on external input information.

13. The memory system of claim 11, wherein the first data reader stores data repeatedly read from the main memory in the sub-memory.

14. The memory system of claim 13, wherein the first data reader stores only data first read or most recently read from the repetitive read address of the main memory in the sub-memory.

15. The memory system of claim 13, wherein the first data reader stores only a predetermined number of bits of the data read from the repetitive read address in the sub-memory.

16. The memory system of claim 11, wherein the controller sends signals indicating a beginning and an end of repetitive reading to the second data reader, and the second data reader reads data from the sub-memory during the repetitive reading.

17. The memory system of claim 16, wherein the sub-memory comprises:
a first memory area for storing data repeatedly read from the repetitive read address of the main memory; and
a second memory area for storing at least of all data read from a particular address of the main memory, 1-bit data read from a particular input/output (I/O) number of each address of the main memory, and a parity bit calculated per address of the main memory,
wherein the second data reader reads the data from the first memory area during the repetitive reading and otherwise reads the data from the second memory area.

18. The memory system of claim 1, wherein the comparator determines existence of an attack when the first data is different from the second data and outputs an attack warning signal to the controller.

19. The memory system of claim 1, wherein the comparator reads the first data and simultaneously compares the first data and the second data.

20. The memory system of claim 1, wherein the comparator compares the first data with the second data after the first data reader reads the first data from an address corresponding to the address information and before the first data reader reads data from a subsequent address.
